(19) United States
(12) Patent Application Publication
(10) Pub. No.: US 2010/0219514 A1
(43) Pub. Date: Sep. 2, 2010

(54) SEMICONDUCTOR DEVICE

(75) Inventor: Tatsuya Ohguro, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/714,768

(22) Filed: Mar. 1, 2010

(30) Foreign Application Priority Data
Mar. 2, 2009 (JP) 2009-48440

(51) Int. Cl. H01L 23/552

(52) U.S. Cl. 257/659; 257/E23.114

(57) ABSTRACT

A semiconductor device includes: a first region, a second region and a third region surrounding the second region; an integrated circuit including an active element in the first region and provided in and above a first substrate; an antenna which is provided in the second region, connected to the integrated circuit and configured to receive or transmit a high-frequency signal; and a first shield layer which is grounded and includes a stack of a plurality of conductive layers in the third region.

### CROSS REFERENCE TO RELATED APPLICATION

This application claims benefit of priority under 35USC §119 to Japanese Patent Application No. 2009-048440, filed on Mar. 2, 2009, the contents of which are incorporate by reference herein.

### BACKGROUND

In recent years, the utilization of high-frequency signals having a wavelength in units of a millimeter has been increased. This causes development in practical application of an on-chip antenna constituted of, for example, a semiconductor chip and an antenna mounted thereon.

Signals outputted from the antenna will be directed toward layers having a higher dielectric constant. Therefore, in the case that a chip is made of, for example, a silicon substrate, if a protective resin which covers the antenna has a dielectric constant of, for example, 4.3, the signal is externally outputted mainly through the silicon substrate on which multi-layer interconnections are formed because the silicon substrate has a dielectric constant of 11. However, it has a problem in that when passing through the silicon substrate via the multi-layer interconnections, the output signal enters an integrated circuit with a variety of elements as noise, thus deteriorating properties of the integrated circuit (see, for example, Japanese Patent No. 4141881).

### SUMMARY

According to a first aspect of the present invention, there is provided a semiconductor device comprising:

a first, second and third regions, the third region surrounding the second region;

an integrated circuit comprising an active element in the first region and provided in and above a first substrate;

an antenna in the second region connected to the integrated circuit, the antenna being configured to receive or transmit a high-frequency signal and provided above the first substrate; and

a first shield layer comprising a stack of a plurality of conductive layers in the third region, the first shield layer being grounded.

### BRIEF DESCRIPTION OF THE DRAWINGS

FIGS. 1A and 1B are a cross-sectional view and a plan view showing an outlined constitution of a semiconductor device according to a first embodiment of the present invention;

FIG. 2 is an explanatory diagram of a manufacturing method of the semiconductor device shown in FIGS. 1A and 1B;

FIGS. 3A to 7B are explanatory diagrams of the manufacturing method of the semiconductor device shown in FIGS. 1A and 1B;

FIG. 8 is a plan view of a shield layer of the semiconductor device shown in FIGS. 1A and 1B;

FIG. 9 is a cross-sectional view showing a first modification of the semiconductor device shown in FIGS. 1A and 1B;

FIG. 10 is a graph showing a relationship between a substrate resistance and an antenna efficiency;

FIG. 11 is a cross-sectional view showing an outlined constitution of a semiconductor device according to a second embodiment of the present invention;

FIGS. 12A to 13B are explanatory diagrams of a manufacturing method of the semiconductor device shown in FIG. 11;

FIGS. 14A to 14C are cross-sectional views showing an outlined constitution of a semiconductor device according to a third embodiment of the present invention;

FIGS. 15A to 16 are explanatory diagrams of a manufacturing method of the semiconductor device shown in FIGS. 14A to 14C;

FIGS. 17A and 17B are cross-sectional views showing an outlined constitution of a semiconductor device according to a fourth embodiment of the present invention; and

FIG. 18 is a cross-sectional view showing one modification of the semiconductor device shown in FIGS. 17A and 17B.

### DETAILED DESCRIPTION

Hereafter, an explanation will be given in detail of several embodiments of the present invention with reference to the drawings. In the accompanying drawings, identical reference numerals are given to similar components, and repetitive description on the similar components will be appropriately omitted.

### (1) First Embodiment

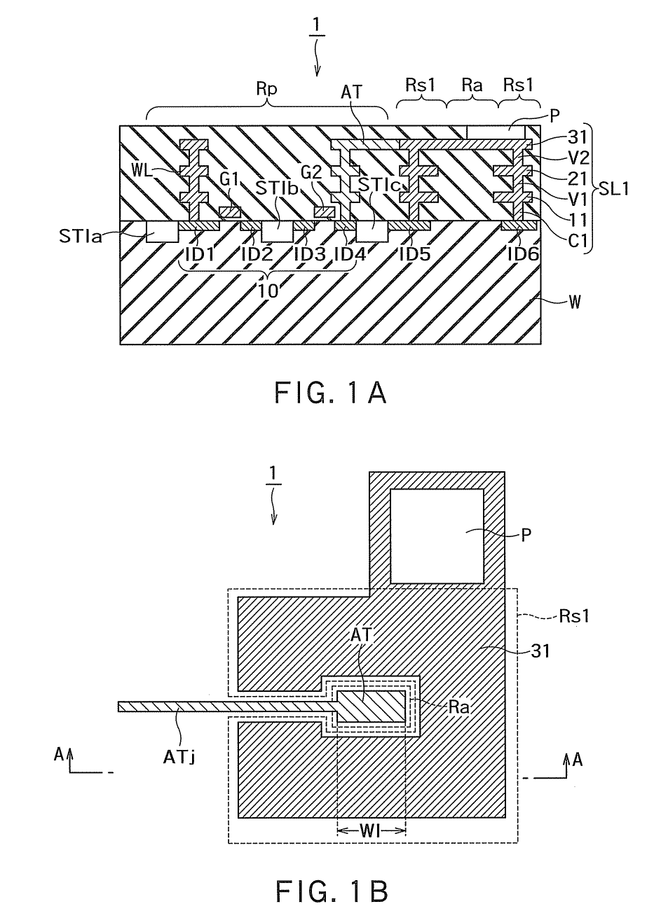

FIG. 1A is the cross-sectional view showing the outlined constitution of a semiconductor device according to a first embodiment of the present invention and FIG. 1B is a partial plan view of the semiconductor device shown in FIG. 1A.

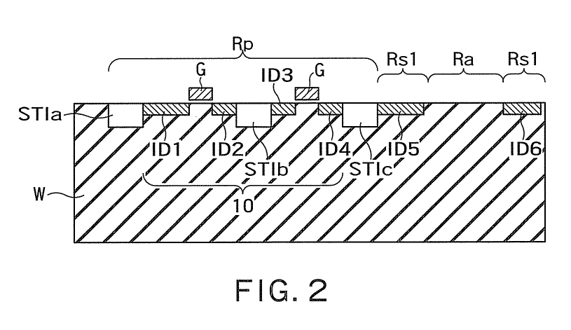

A semiconductor device 1 shown in FIGS. 1A and 1B includes an element formation region Rp, an antenna formation region Ra, and a shield layer formation region Rs1 which encloses the antenna formation region Ra, a silicon substrate W, active elements 10, an interconnection layer WL, an on-chip antenna AT, and a shield layer SL1 charactristic of the present embodiment. In the present embodiment, the silicon substrate W corresponds to, for example, a first substrate, the element formation region Rp corresponds to, for example, a first region, the antenna formation region Ra corresponds to, for example, a second region, and, further, the shield layer formation region Rs1 corresponds to, for example, a third region. It is to be noted that FIG. 1B is a plan view of the antenna formation region Ra and the shield layer formation region Rs1 in the semiconductor device 1 and FIG. 1A is a cross-sectional view taken along line A-A of FIG. 1B. The relationship between the cross-sectional view and the plan view in the respective FIGS. 1A and 1B also applies to FIGS. 2 to 7B, 9, and 11 to 18.

The active element 10 is a power amplifier formed in the element formation region Rp on the side of a main surface of the silicon substrate W and constituted of a CMOS in the present embodiment, but not limited to it, and may be constituted of, for example, a bipolar transistor. The interconnection layer WL is also formed in the element formation region Rp above the silicon substrate W and connected via a contact to, for example, an impurity diffusion layer ID1 in an NMOS.

The on-chip antenna AT is formed in the antenna formation region Ra in almost the uppermost layer of the semiconductor device 1. The on-chip antenna AT outputs a high-frequency signal when it is connected to the drain of an MOSFET which uses a gate G2 as its control electrode and impurity diffusion layers IDL3 and IDL4 of the active elements 10 as its source and drain, respectively. Further, the on-chip antenna AT receives a high-frequency signal and, if connected to a low noise amplifier (LNA), not shown, via a selector switch (not shown), supplies the received signal to this LNA. The high-frequency signal is inputted and sent to the integrated circuit. Here, the high-frequency signal refers to a signal which has a frequency of at least, for example, 300 MHz. It is to be noted that as described above, signals outputted from the antenna will be directed toward layers having a higher dielectric constant, that is, not upward from the on-chip antenna AT but toward a back surface side of the silicon substrate W through it. Therefore, in order to prevent a drop in power efficiency, no elements other than the antenna are formed in the antenna formation region Ra.

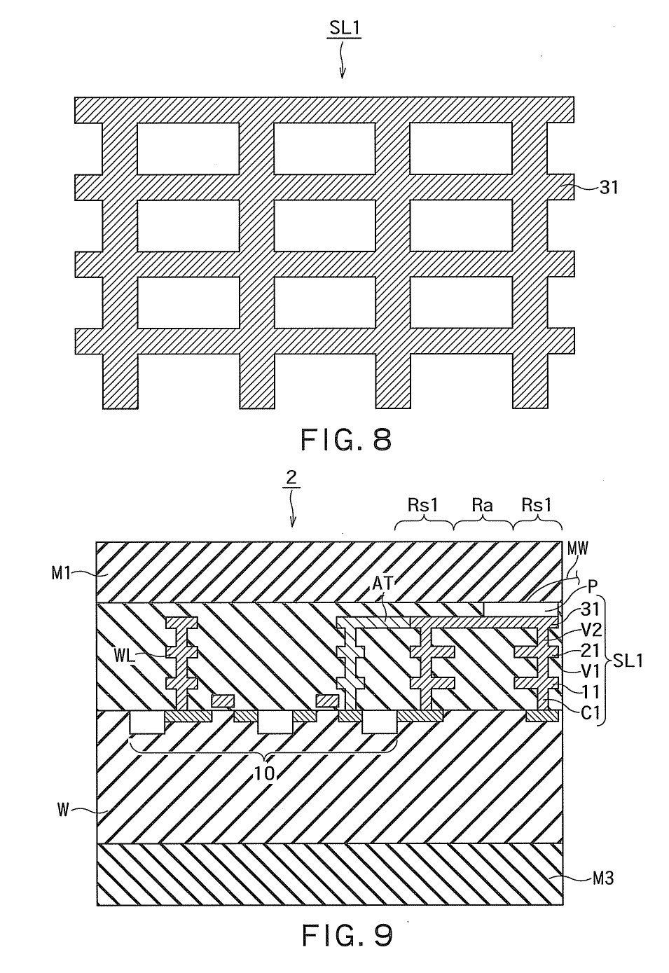

The shield layer SL1 corresponds to, for example, a first shield layer in the present embodiment and is formed of conductive layers stacked in the shield layer formation region Rs1 of the silicon substrate W. The conductive layers are comprised of a contact C1, a first conductive layer 11, a first via V1, a second conductive layer 21, a second via V2, and a third conductive layer 31 which are sequentially formed in such a manner that they contact each other from the layer on the impurity diffusion layers ID5 and ID6 formed in the same layer as the impurity diffusion layers ID1 to ID4 of the CMOS, up to the same layer as the on-chip antenna AT. On the third conductive layer 31, a pad P is formed and grounded through a metal wire (see a symbol MW in FIG. 9) or a solder ball (not shown). Thus, the shield layer SL1 is grounded via the pad P, and the entry of a high-frequency signal input or output from the on-chip antenna AT into a circuit block in and/or above the substrate W is resultantly suppressed. As described in detail later, the contact C1, the first conductive layer 11, the first via V1, the second conductive layer 21, and the second via V2 of the shield layer SL1 except for the uppermost third conductive layer 31 are formed and disposed in such a manner as to constitute a closed loop that encloses the on-chip antenna AT in a plan view. The uppermost third conductive layer 31 is formed in the same layer as the on-chip antenna AT in a manner that part of the closed loop is opened in order to lead out a connection ATj with the integrated circuit.

Next, an explanation will be given of a method for manufacturing the semiconductor device shown in FIG. 1 more specifically with reference to FIGS. 2 to 7.

First, as shown in a cross-sectional view of FIG. 2, the active element 10, for example, a CMOS is formed in the main surface of the silicon substrate W. In this case, the impurity diffusion layers ID5 and ID6 are also formed together in the shield layer formation region Rs1.

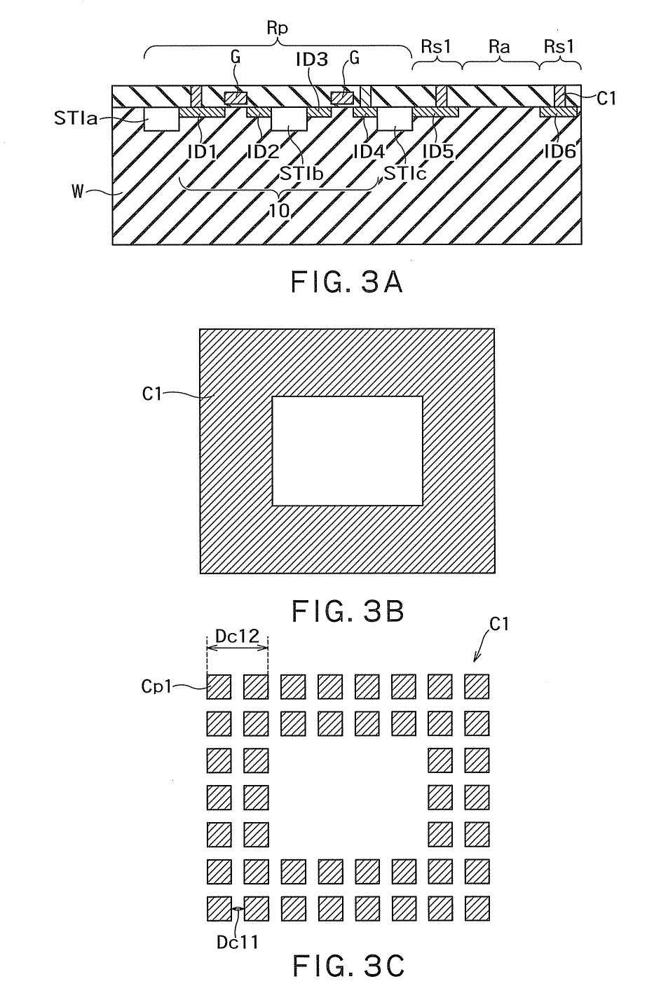

Next, as shown in a cross-sectional view of FIG. 3A, together with the process in which a contact is formed for the impurity diffusion layers ID1 to ID4 of the CMOS in the element formation region Rp, the contact C1 which interconnects the impurity diffusion layers ID5 and ID6 is also formed in the shield layer formation region Rs1. The contacts C1 may be continuous in shape so as to enclose the on-chip antenna AT in a plan view as shown in FIG. 3B or may be comprised of vertically (perpendicularly with respect to the sheet) spindly pillar-shaped conductors CP1 which are disposed in a closed-loop shape so as to surround the on-chip antenna AT in a plan view as shown in FIG. 3C.

Although in the present embodiment the conductors CP1 are disposed in a lattice shape in such a manner as to form a matrix, the present invention is not limited to it; they may be disposed irregularly. However, a distance Dc11 between the conductors CP1 needs to be ⅛ or less of a wavelength calculated from the frequency of a signal outputted from or inputted to the on-chip antenna AT. This is because if the conductors CP1 are separated from each other more than necessary and then the distance Dc11 between the conductors CP1 is increased more than necessary, the phases of the signals flowing through the mutually adjacent conductors CP1 become too close to each other and there may appear a situation as if a current propagates between conductors CP1. In the case of inputting or outputting a high-frequency signal of, for example, 60 GHz, its wavelength is about 5 mm, the distance Dc11 between the conductors CP1 then needs to be 600 μm or less. This space value can be realized sufficiently in an LSI manufacturing process.

Further, to obtain sufficient shielding effects, a distance Dc12 between an inner side surface and an outer side surface of the contact C1 needs to be larger than a skin depth (=(ρ/(πfη)^{1/2}). Here, ρ indicates the resistivity of a metal buried in the contact C1, f indicates the frequency of a signal, and η indicates the magnetic permeability of the metal buried in the contact C1.

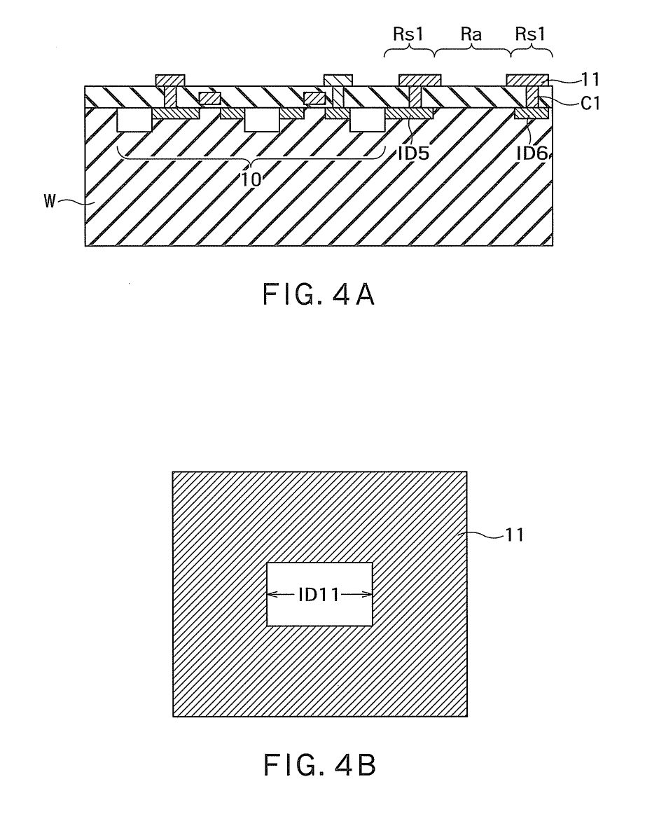

Next, as shown in a cross-sectional view of FIG. 4A, the first conductive layer 11 is formed to be in contact with the contact C1. The conductive layer 11 is a closed loop-shaped continuous layer to enclose the on-chip antenna AT as shown in FIG. 4B and has its inner diameter ID11 larger than a width W1 of the on-chip antenna AT (see FIG. 1B). The inner diameter ID11 corresponds to, for example, a distance between inner side surfaces in the present embodiment.

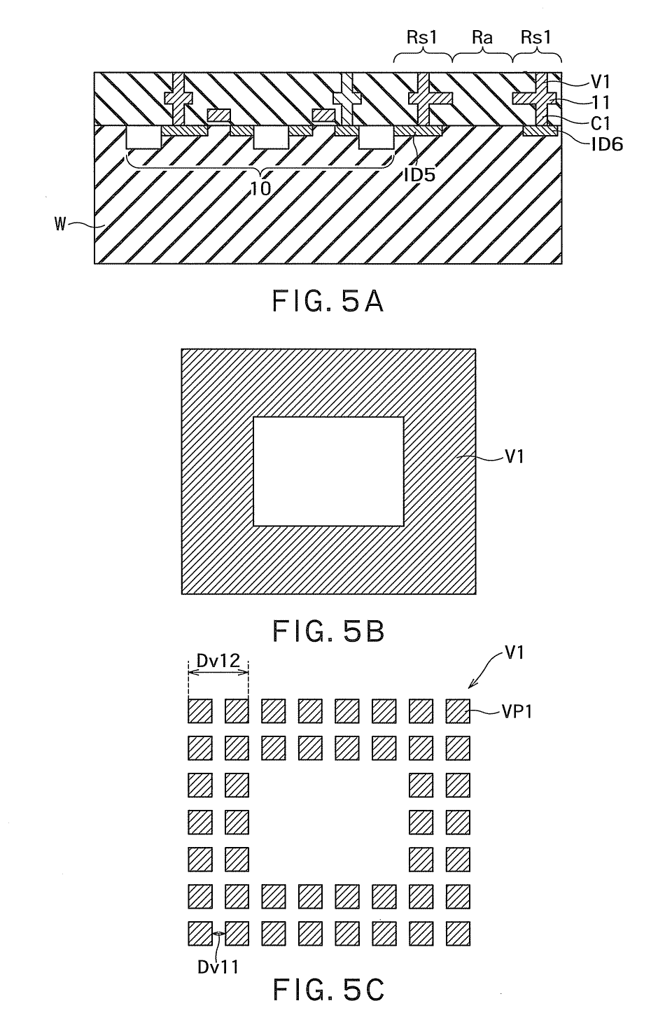

Subsequently, as shown in FIG. 5A, the via V1 which is in contact with the first conductor layer 11 is formed in the shield layer formation region Rs1. Similar to FIGS. 3B and 3C, the via V1 may be continuous in shape like a closed loop in a plan view so as to avoid the region in which the on-chip antenna AT is to be formed or comprised of vertically (perpendicularly with respect to the sheet) spindly pillar-shaped conductors VP1 which are disposed in the above-mentioned closed loop. In the case of constituting the via V1 with the pillar-shaped conductors VP1, similar to the aforesaid distance Dc11 between the conductors CP1, a distance Dv11 between the conductors VP1 needs to be ⅛ or less of a wavelength calculated from the frequency of a signal inputted to or outputted from the on-chip antenna AT. It is to be noted that the contact C1 and the via V1 may be at the same position or different positions in a plan view as long as they are connected to the first conductor layer 11 through an interconnection not shown. This is because as long as the Dc11 between the spindly pillar-shaped conductors CP1 and the distance Dv11 between the conductors VP1 are each ⅛ or less of a wavelength calculated from the frequency of a signal inputted to or outputted from the on-chip antenna AT, almost the same effects will be obtained irrespective of the position of the contact or the via.

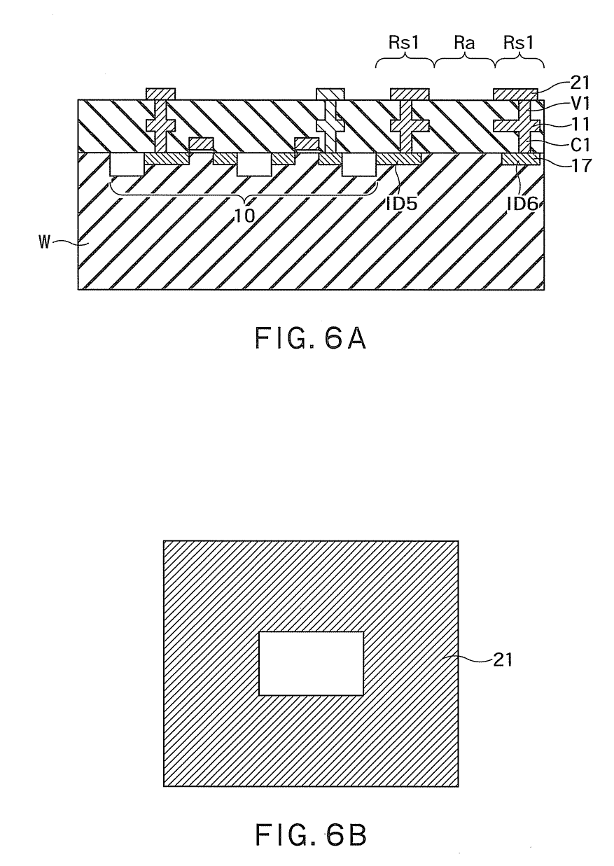

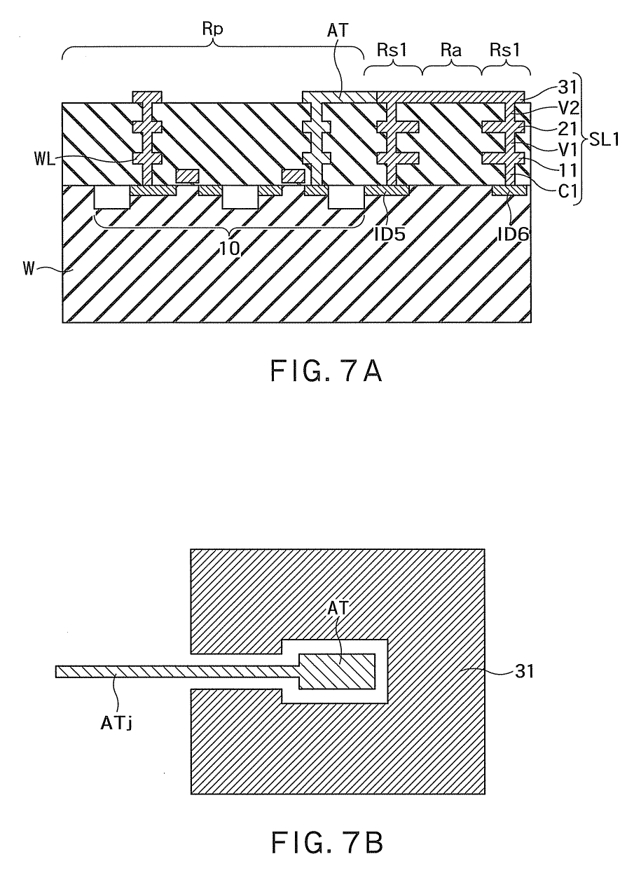

Next, as shown in FIG. 6A, the second conductor 21 is formed on the via V1, as is the case with the first conductor layer 11. In this case also, as shown in FIG. 6B, the via V1 is continuous and closed loop-shaped like the first conductor layer 11. Further, like the via V1, the via V2 is formed on the second conductor layer 21 and then, as shown in FIG. 7A, the third conductor layer 31 is formed in a layer in which the on-chip antenna AT is to be formed. In this case, as described above, the third conductive layer 31 is formed in such a manner that part of the closed loop is opened in a plan view as shown in FIG. 7B in order to lead out the connection ATj with the integrated circuit.

A plan view of the shield layer SL1 thus formed by these processes is shown in FIG. 8. As shown in FIG. 8, the shield layer SL1 is shaped like a mesh as a whole.

### (First Variant)

FIG. 9 is a cross-sectional view showing the first modification of the present embodiment. As may be clear from comparison to FIG. 1A, a semiconductor device 2 of the present modification further includes a molding resin M1 formed on the main surface side of a substrate W and a molding resin M3 formed on the back surface side of the substrate W, in addition to the constitution of the semiconductor device 1. In the present modification, the molding resins M1 and M3 correspond to, for example, first and second molding resins, respectively. The molding resin M3 has a dielectric constant of about 3.5 that is larger than that of the air of 1.5 and so can improve the efficiency of output from an on-chip antenna AT as compared to the semiconductor device 1 shown in FIG. 1A.

### (Second Variant)

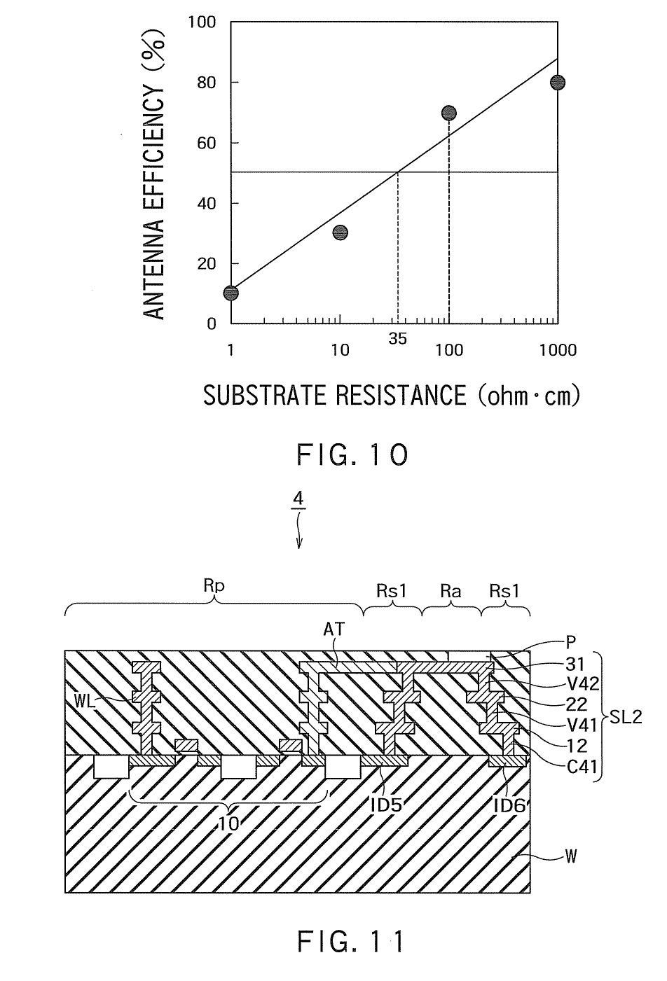

FIG. 10 is a graph showing the relationship between a substrate resistance and an antenna efficiency. As shown in FIG. 10, the higher the substrate resistance is, the more the antenna efficiency is improved. Therefore, if the substrate resistance is about 35 Ω or higher, at least the millimeter-wave requirement specification S (50%) is satisfied. Thus, in the second modification of the present embodiment, by using a silicon substrate having a substrate resistance of at least 35 Ω as the substrate, the efficiency of output from the on-chip antenna AT can be improved further as compared to the semiconductor device 1 shown in FIG. 1A.

### (2) Second Embodiment

FIG. 11 is a cross-sectional view showing the outlined constitution of a semiconductor device according to the second embodiment of the present invention. As may be clear from comparison to FIG. 1A, the feature of a semiconductor device 4 shown in FIG. 11 is that its shield layer SL2 is formed in such a manner that a conductive layer has an increasing inner diameter as it comes down from a third conductive layer 31 formed in the same layer as an on-chip antenna AT. That is, a first conductive layer 12 has a larger inner diameter than a second conductive layer 22, a via V41 has a larger inner diameter than a via V42, and a contact C41 has a larger inner diameter than the via V41.

By thus changing a layout so that the conductive layer has the step-wise increasing inner diameter as it comes down from the layer formed in the same layer as the on-chip antenna AT, the shield layer SL2 can have the shape of a horn antenna as a whole, thus further improving the efficiency of output from the on-chip antenna AT. The shield layer SL2 corresponds to, for example, a first shield layer in the present embodiment.

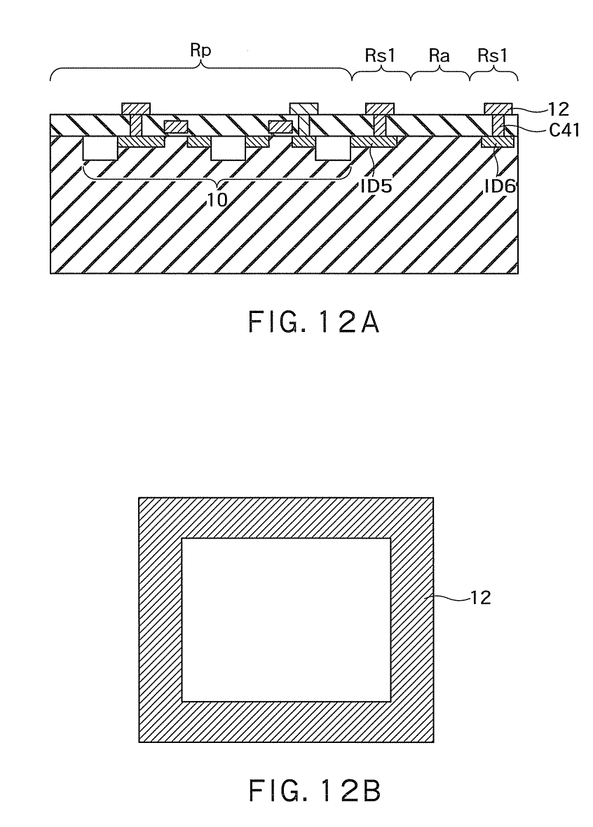

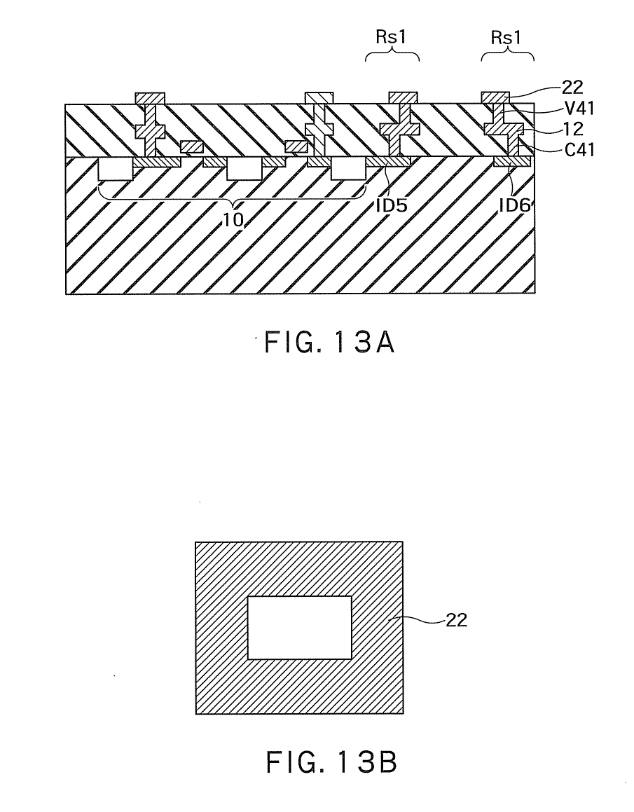

Such a semiconductor device 4 can be manufactured by, as shown in FIGS. 12A to 13B, preparing a layout having an inner diameter enlarged beforehand and forming the shield layer SL2 in such a manner that the inner diameter decreases upward through the stack layers of the contact C41, the first conductive layer 12, the via V41, the second conductive layer 22, and the via V42 in this order.

### (3) Third Embodiment

In accordance with the first and second embodiments, it is possible to prevent a signal input to or output from the on-chip antenna AT from directly entering a circuit block in the silicon substrate W by using the shield layers SL1 and SL2 comprised of a stack of the conductive layers.

However, there are some signals that might enter the silicon substrate W for any reason, so that it is required to prevent such signals from indirectly entering the circuit block through the silicon substrate W. The present embodiment is intended for preventing a signal in the silicon substrate W from entering the circuit block by forming a penetrating via in the back surface side of the silicon substrate W.

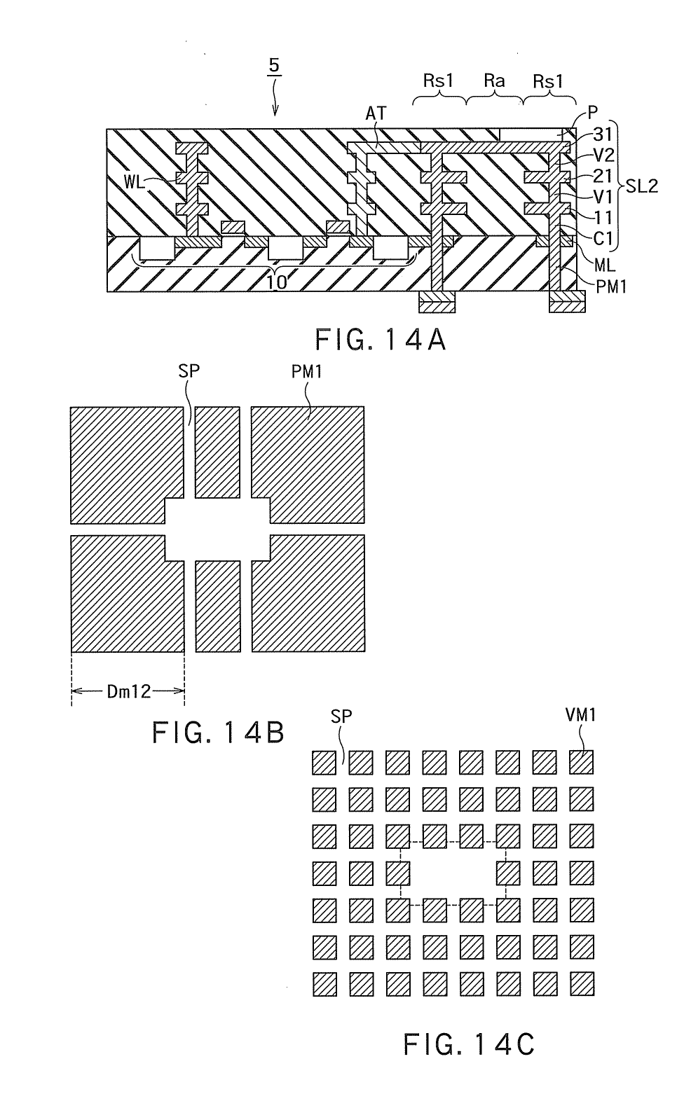

FIGS. 14A to 14C are cross-sectional views showing the outlined constitution of a semiconductor device of the present embodiment. As may be clear from comparison to FIG. 1A, a semiconductor device 5 shown in FIG. 14A further includes a via metal layer PM1 obtained by filling a penetrating via formed in the back surface of the silicon substrate W in such a manner that it reaches a contact C1 in the shield layer SL1, with a metal material. In the semiconductor device 5, by forming the via metal layer PM1 so that it comes in contact with the contact C1, the via metal layer PM1 is grounded via the shield layer SL1 and a pad P. In the present embodiment, the via metal layer PM1 corresponds to, for example, a second shield layer. It is to be noted that in the present embodiment, a metal layer ML is substituted for the impurity diffusion layers ID5 and ID6 shown in FIG. 1.

It is to be noted that as described later, in forming the penetrating via, in order to avoid a drop in input/output efficiency of high-frequency signals, it is not preferable to remove a silicon layer in an antenna formation region Ra. Therefore, the via metal layer PM1 cannot be formed to have a closed-loop planar shape but it has to be formed to have a shape divided by a space SP as shown in FIG. 14B. Further, as described above with the first embodiment, a distance Dm12 between an inner side surface and an outer side surface of the via metal layer PM1 in a plan view needs to be larger than a skin depth (=(ρ/(πfη)^{1/2}). Incidentally, as shown in FIG. 14C, in the case of constituting the via metal layer PM1 of a vertically (perpendicularly with respect to the sheet) spindly pillar-shaped metal layer VM1, there are no needs for further division thereof.

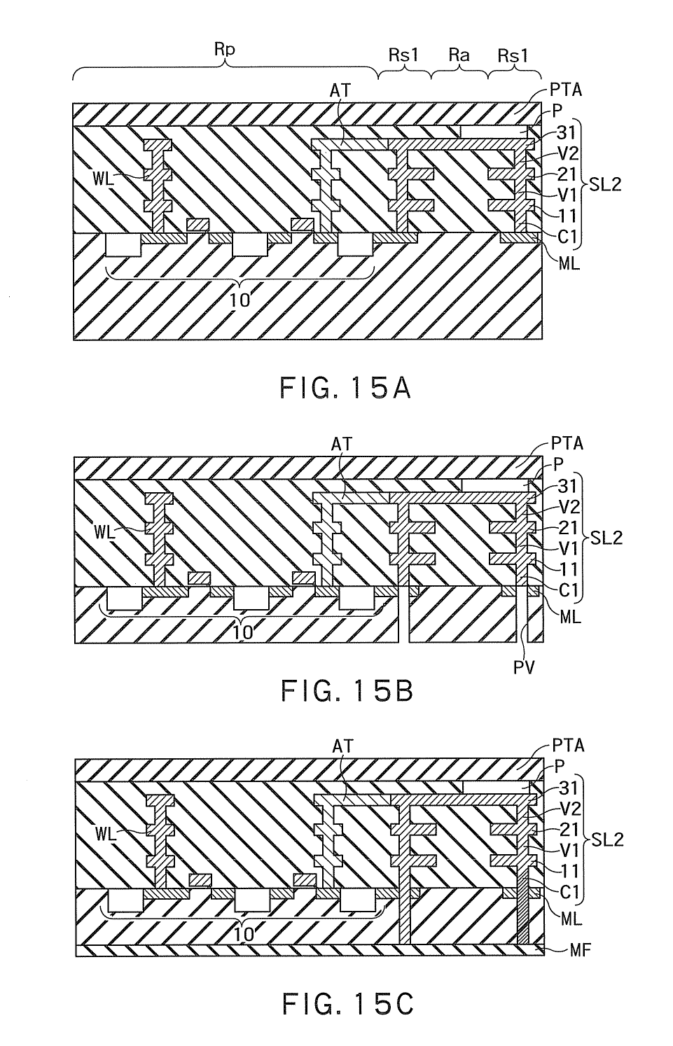

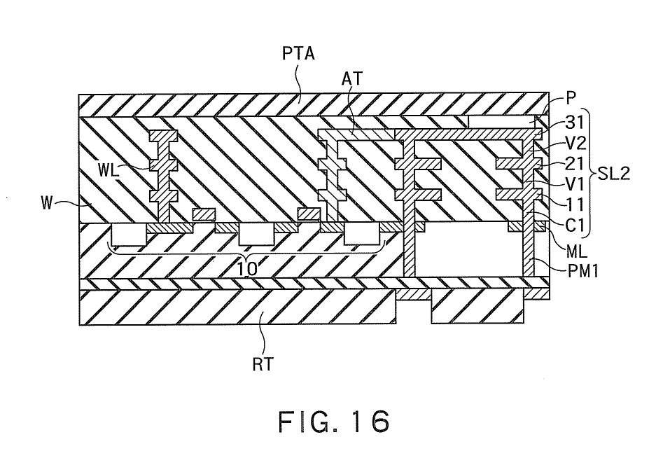

An explanation will be given of a method for manufacturing the semiconductor device 5 of the present embodiment with reference to FIGS. 15A to 16.

Processes of manufacturing the semiconductor device 5 of the present embodiment are essentially the same as those described with the first embodiment with reference to FIGS. 2 to 7B except that the metal layer ML is formed in place of the impurity diffusion layers ID5 and ID6. Therefore, an explanation will be given below starting from the process immediately after that of FIG. 7B.

First, as shown in FIG. 15A, a protective tape PTA is applied to an upper surface of the silicon substrate W and the silicon substrate W is then thinned by grinding a back surface thereof.

Next, as shown in FIG. 15B, the back surface of the silicon substrate W is patterned using a resist and then a through via-hole PV is formed in it by dry etching. It is to be noted that the through via-hole PV may be formed by another method of making an opening by using laser rather than the resist. By forming the through via-hole PV, the contact C1 of the shield layer SL1 appears at the bottom surface of the through via-hole PV.

Next, as shown in FIG. 15C, a metal film MF which provides a plated shield layer is formed by sputtering a metal material and patterned by using a resist and then, as shown in FIG. 16, a metal is grown only in an opening in a resist RT. Subsequently, the resist RT is removed, extra portions of the metal film MF used as the shield layer is then removed by using the already grown metal as a mask. Finally, by removing the protective tape PTA, the semiconductor device 5 shown in FIG. 14A is obtained.

### (4) Fourth Embodiment

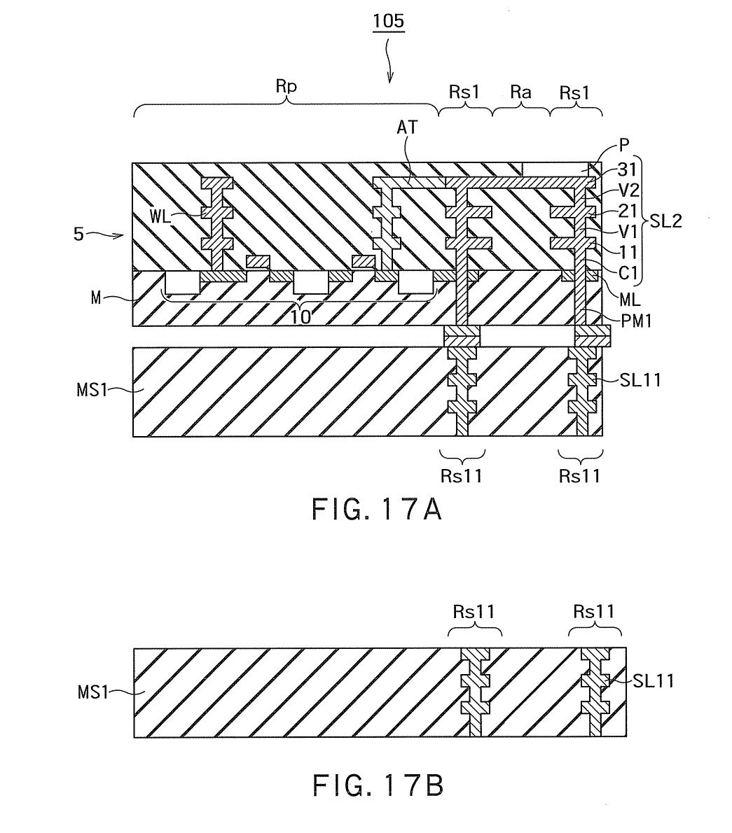

An explanation will be given of a fourth embodiment of the present invention with reference to FIGS. 17A and 17B. A semiconductor device 105 shown in FIG. 17A is given by mounting the semiconductor device 5 of the above-described third embodiment onto a mounting substrate MS 1. It is to be noted that the mounting substrate MS 1 is constituted of a ceramic-made multi-layer interconnection substrate and includes a shield layer SL11 formed of a stack of a plurality of conductive layers in a region Rs11. The region RS11 corresponds to the shield layer formation region Rs1 of the semiconductor device 5. The semiconductor device 5 is mounted by positioning it so that a via metal layer PM1 is connected to the shield layer SL11 on the mounting substrate MS. The shield layer SL11 is grounded through the via metal layer PM1, the shield layer SL2, and the pad P.

In accordance with the present embodiment, it is possible to avoid a signal output to an on-chip antenna AT from being directly directed to an air layer having a dielectric constant of 1 from a silicon substrate W having a dielectric constant of 11, by using the mounting substrate MS1. By selecting a material of the mounting substrate MS1 having a dielectric constant which is smaller than 11 and larger than 1, reflection of the signal output from the silicon substrate W can be reduced. In the present embodiment, the mounting substrate MS is made of a ceramic material having a dielectric constant of about 4.6.

As shown in FIG. 17B, the mounting substrate MS is manufactured by forming the shield layer SL11 in a ceramic substrate by performing multi-layer processes by use of a through via-hole in the above-described third embodiment. It is to be noticed that in the case of the mounting substrate MS 1, the shield layer SL11 is formed in such a manner that its top surface appears at the top surface of the mounting substrate MS1 and its bottom surface also appears at the back surface of the mounting substrate MS1.

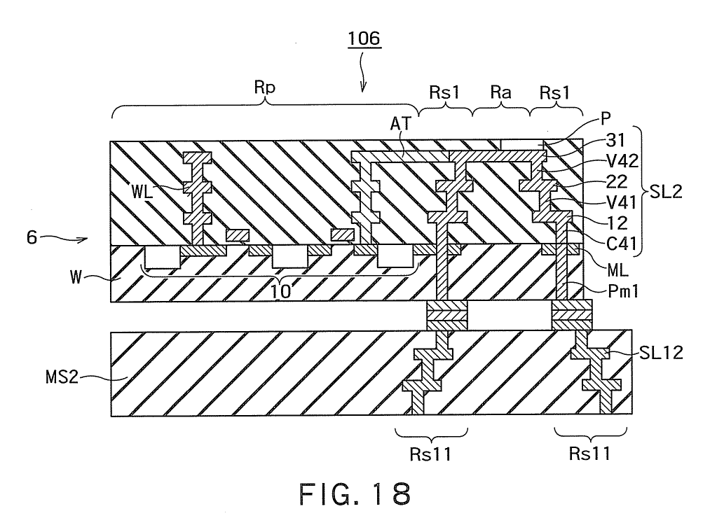

FIG. 18 is a cross-sectional view showing a semiconductor device 106 according to one modification of the present embodiment. In the semiconductor device 106 of the present modification, a semiconductor device 6 including the via metal layer PM1 formed so as to connect to the shield layer SL2 (see FIG. 11) formed in such a manner that inner diameters of the conductive layers step-wise increases downward is mounted on a ceramic-made multi-layer interconnection substrate MS2. Furthermore, a shield layer SL12 is formed on the substrate MS2 in such a manner that the inner diameters of the conductive layers step-wise increases downward by positioning it so that the via metal layer PM1 is connected to the shield layer SL12. By mounting the shield layer SL11 having such a structure also on the mounting substrate MS2, it is possible to further improve the output efficiency of the on-chip antenna AT. In the present embodiment, the mounting substrates MS1 and MS2 correspond to, for example, second substrates, the regions Rs11 and Rs12 correspond to, for example, fourth regions, and further the shield layers SL11 and SL12 correspond to, for example, third shield layers.

Although the embodiments of the present invention have been hereinabove explained, it should be appreciated that the present invention is not limited thereto and can be modified in various manner within the scope thereof. For example, although the above embodiments have been explained with reference to an aspect in which the first shield layer would connect to the second shield layer, the present invention is not limited to it; it need not be connected to the first shield layer as long as it is grounded. Similarly, although the above embodiments have been explained with reference to an aspect in which the third shield layer would be connected via the second shield layer up to the first shield layer, the present invention is not limited to it; it need not be connected to the second shield layer as long as it is grounded. Further, although the above embodiments have been explained with reference to an aspect in which the antenna formation region Ra would be adjacent to the element formation region Rp, the present invention is not limited to it; of course, it can be applied also to a case where the antenna formation region Ra is set in such a manner as to enclose the element formation region Rp as in the case of a close-range communication device using a millimeter wave band of, for example, about 60 GHz.

What is claimed is:

1. A semiconductor device comprising:
a first, second and third regions, the third region surrounding the second region;
an integrated circuit comprising an active element in the first region and provided in and above a first substrate;
an antenna in the second region connected to the integrated circuit, the antenna being configured to receive or transmit a high-frequency signal and provided above the first substrate; and
a first shield layer comprising a stack of a plurality of conductive layers in the third region, the first shield layer being grounded.

2. The semiconductor device of claim 1,
wherein the antenna is provided in a layer adjacent to a surface of the semiconductor device.

3. The semiconductor device of claim 1,
wherein no elements in the second region other than the antenna are provided.

4. The semiconductor device of claim 1, further comprising a pad on the first shield layer,
wherein the first shield layer is grounded via the pad.

5. The semiconductor device of claim 4, further comprising a fourth region surrounding the third region,
wherein the pad is formed in the fourth region,
the first shield layer comprises conductors of a plurality of layers above the first substrate, the plurality of layers being connected to each other by vias, and
a conductor in the uppermost layer of the conductors constituting the first shield layer comprises an extension portion configured to extend up to the fourth region and to be connected to the pad.

6. The semiconductor device of claim 1,
wherein the first shield layer comprises conductors of a plurality of layers above the first substrate, the plurality of layers being connected to each other by vias,
the conductors are configured to become a closed-loop surrounding the antenna except for the conductor in the uppermost layer of the shape that part of the closed-loop is opened, and
the antenna further comprises a connection portion above the open part of the closed-loop configured to be connected to the active element.

7. The semiconductor device of claim 1,
wherein a distance between inner side surfaces of the first shield layer increases step-wise from a position at which the antenna is provided to a surface of the first substrate.

8. The semiconductor device of claim 1,
wherein the first shield layer comprises conductors of a plurality of layers above the first substrate, the plurality of layers being connected to each other by vias, and
each conductor has a continuous shape in a plan view.

9. The semiconductor device of claim 1,
wherein the first shield layer comprises pillar-shaped conductors of a plurality of layers above the first substrate, the pillar-shaped conductors being disposed in a closed-loop shape, and
a distance between the conductors is ⅛ or less of a wavelength of the high-frequency signal.

10. The semiconductor device of claim 9,
wherein assuming a resistivity of the conductors to be ρ, a magnetic permeability of the conductors to be η, and a frequency of the signal transmitted and received by the antenna to be f, the distance between an inner side surface and an outer side surface of the mutually adjacent pillar-shaped conductors is larger than (ρ/(πfη)^{1/2}).

11. The semiconductor device of claim 1, further comprising a first molding resin on a main surface side of the first substrate.

12. The semiconductor device of claim 11, further comprising a second molding resin on a back surface side of the first substrate opposite the main surface side.

13. The semiconductor device of claim 1, further comprising a first molding resin on a back surface side of the first substrate opposite a main surface side thereof.

14. The semiconductor device of claim 1,
wherein the antenna is located on a main surface side of the first substrate, and
the semiconductor device further comprises a second shield layer of a conductive material buried in a through via-hole from a back surface of the first substrate opposite the main surface toward the first shield layer in the third region.

15. The semiconductor device of claim 14, wherein
the second shield layer comprises pillar-shaped conductors separated from each other, and
assuming a resistivity of the conductors to be ρ, a magnetic permeability of the conductors to be η, and a frequency of the signal transmitted and received by the antenna to be f, the distance between an inner side surface and an outer side surface of the pillar-shaped conductors is larger than (ρ/(πfη)^{1/2}).

16. The semiconductor device of claim 14,
wherein a distance between inner side surfaces in at least one of the first and second shield layers increases step-wise from the main surface side toward the back surface side.

17. The semiconductor device of claim 14, further comprising:
a second substrate on the first substrate; and
a third shield layer comprising a stack of a plurality of conductive layers in a fourth region in the second substrate facing the third region in the first substrate.

18. The semiconductor device of claim 17,
wherein a distance between inner side surfaces in at least any one of the first through third shield layers increases step-wise from the main surface side toward the back surface side.

19. The semiconductor device of claim 17,
wherein the magnetic permeability of the second substrate is larger than 1 and smaller than 11.

20. The semiconductor device of claim 1,
wherein the second region surrounds the first region.
